(19) United States
(12) Patent Application Publication
(10) Pub. No.: US 2012/0043562 A1
(43) Pub. Date: Feb. 23, 2012

(54) ORGANIC ELECTROLUMINESCENCE DISPLAY DEVICE AND MANUFACTURING METHOD THEREFOR

(75) Inventor: Nobutaka Ukigaya, Mobara-shi (JP)

(73) Assignee: CANON KABUSHIKI KAISHA, Tokyo (JP)

(21) Appl. No.: 13/189,902

(22) Filed: Jul. 25, 2011

(30) Foreign Application Priority Data
Aug. 19, 2010 (JP) 2010-183874

(51) Int. Cl. H01L 33/02

(52) U.S. Cl. 257/88; 438/34; 257/103; 257/E33.013

(57) ABSTRACT

Provided is an organic eletroluminescence display device, which is capable of preventing transfer of an attached matter from the vapor deposition mask to the insulating layer, without increasing steps or manufacturing cost. The organic eletroluminescence display device includes: a first insulating layer formed on a substrate; multiple first electrodes disposed on the first insulating layer; an opening formed in the first insulating layer at a periphery of the first electrode; a second insulating layer disposed in a region overlapping with the opening; an organic compound layer covering the first electrodes; and a second electrode formed on the organic compound layer, in which: a material forming the first electrodes is absent in the opening; and the second insulating layer has a recess formed in a surface thereof, reflecting the opening of the first insulating layer, the recess being formed in a vertical direction of the substrate surface.

### BACKGROUND OF THE INVENTION

1. Field of the Invention

The present invention relates to an organic electro luminescence (EL) display device including multiple organic EL elements each having organic compound layers containing an emission layer between electrodes, and to a manufacturing method therefor.

2. Description of the Related Art

In recent years, as a flat panel display, an organic EL display device that is a self-emission device has attracted attention and has been developed actively.

On a substrate of such an organic EL display device, multiple first electrodes are arranged in matrix, and organic compound layers expressing different light emission colors are respectively formed on the first electrodes by a vacuum deposition method. In this case, a vapor deposition mask having multiple pixel apertures is brought into contact with the surface of an insulating layer having a protruding shape, so as to expose the first electrodes corresponding to pixels.

Here, the insulating layer, which has an element separating function and a width corresponding to an interval between pixels, is disposed so as to surround the perimeter of each pixel. Therefore, a contact area between the insulating layer and the vapor deposition mask is increased. As a result, when the vapor deposition mask is pressed to contact with the surface of the insulating layer, an attached matter such as a foreign substance adhered to the vapor deposition mask is easily transferred to the surface of the insulating layer. Accordingly, when a tension is applied to the vapor deposition mask, the surface of the insulating layer may be damaged due to a scratch by rubbing. If the insulating layer is damaged, moisture may easily enter through the damaged part, and hence the emission life may be shortened. In addition, if the attached matter on the vapor deposition mask enters a light emitting part in the pixel aperture, the organic compound layer formed inside is easily disconnected in a vicinity of the foreign substance, resulting in an emission defect caused by a short-circuit between electrodes.

As a measure for eliminating such a trouble, for example, there is proposed a structure in which a part of the insulating layer is protruded upward so as to form a rib so that the vapor deposition mask contacts with the rib, thereby reducing a contact area with the vapor deposition mask (Japanese Patent Application Laid-Open No. 2005-322564).

By the way, it is necessary for forming the rib protruding on the insulating layer to perform a pattern exposure for partially controlling an exposure amount in a step of forming the insulating layer and to perform two photolithography steps. In order to partially control the exposure amount, for example, a method of using two photomasks and a method of using a halftone mask are employed, each of which, however, causes an increase in the number of steps and an increase in manufacturing cost due to increasing cost of the photomask. Thus, there has been a problem in productivity.

### SUMMARY OF THE INVENTION

Therefore, an object of the present invention is to provide an organic EL display device and a manufacturing method therefor, which are capable of reducing a contact area between a vapor deposition mask and an insulating layer arranged around each pixel so as to prevent transfer of an attached matter from the vapor deposition mask to the insulating layer, without increasing the number of steps or manufacturing cost.

The following is a structure of the present invention for achieving the above-mentioned object.

That is, an organic EL display device according to the present invention includes a first insulating layer formed on a substrate, multiple first electrodes disposed on the first insulating layer, one of a first opening and a first recess formed in the first insulating layer at a periphery of each of the multiple first electrodes, a second insulating layer that covers the one of the first opening and the first recess, and has second openings corresponding to the multiple first electrodes, an organic compound layer disposed on the each of the multiple first electrodes and a second electrode formed on the organic compound layer, in which a material forming the each of the multiple first electrodes is absent in the one of the first opening and the first recess and the second insulating layer has a second recess formed in a surface thereof, corresponding to the one of the first opening and the first recess of the first insulating layer.

Further, a method of manufacturing an organic EL display device according to the present invention includes forming a first insulating layer on a substrate, forming one of a first opening and a first recess in the first insulating layer, forming multiple first electrodes on the first insulating layer, forming a second insulating layer having second openings corresponding to the multiple first electrodes in regions overlapping with the one of the first opening and the first recess, forming an organic compound layer for covering the multiple first electrodes by bringing a vapor deposition mask into contact with a surface of the second insulating layer and forming a second electrode on the organic compound layer, in which the forming multiple first electrodes is performed so that a material forming each of the multiple first electrodes is absent in the one of the first opening and the first recess of the first insulating layer and the forming a second insulating layer includes forming the second insulating layer corresponding to the first opening of the first insulating layer, and forming a second recess in the surface of the second insulating layer.

According to the present invention, the contact area between the vapor deposition mask and the insulating layer arranged around each pixel can be reduced so as to prevent transfer of an attached matter from the vapor deposition mask to the insulating layer, without increasing the number of steps or manufacturing cost. Therefore, it is possible to obtain an excellent effect that the surface of the insulating layer is hardly damaged by abrasion or scratch due to transfer of an attached matter from the vapor deposition mask, to thereby prevent entrance of moisture so that the risk of a short-circuit between electrodes can be reduced.

Further features of the present invention will become apparent from the following description of exemplary embodiments with reference to the attached drawings.

### BRIEF DESCRIPTION OF THE DRAWINGS

FIGS. 1A and 1B are schematic diagrams illustrating a cross-sectional structure in a manufacturing process of an organic EL display device according to an embodiment of the present invention.

FIG. 2 is a schematic diagram illustrating a plane structure in the manufacturing process of the organic EL display device according to the embodiment of the present invention.

FIGS. 3A, 3B, 3C, 3D and 3E are schematic diagrams illustrating a cross sectional structure in a manufacturing process of an organic EL display device, taken along the line A-A of FIG. 2.

FIG. 4 is a schematic diagram illustrating another example of the cross sectional structure taken along the line A-A of FIG. 2.

FIG. 5 is an explanatory diagram illustrating a plane state in which a vapor deposition mask is brought into contact with a second insulating layer in a manufacturing method for the organic EL display device according to the embodiment of the present invention.

FIG. 6 is a circuit diagram illustrating an example of an equivalent circuit of the organic EL display device according to the embodiment of the present invention.

FIG. 7 is a schematic diagram illustrating a state in which a force is applied to the backside of a substrate so that the surface of the second insulating layer on the substrate is pressed to the surface of the vapor deposition mask in the manufacturing process for the organic EL display device according to the embodiment of the present invention.

FIGS. 8A, 8B and 8C are schematic diagrams illustrating plane structures of recesses in the second insulating layer and openings in a first insulating layer in the organic EL display device according to the embodiment of the present invention.

### DESCRIPTION OF THE EMBODIMENT

Preferred embodiments of the present invention will now be described in detail in accordance with the accompanying drawings, but the present invention is not limited to this embodiment. Note that, for convenience sake of description, each layer is illustrated in a recognizable size in the drawings, and the scale of the drawings is different from an actual one. In addition, as to matters that are not particularly described in this specification or not particularly illustrated in the drawings, well-known or publicly-known technologies shall be applied.

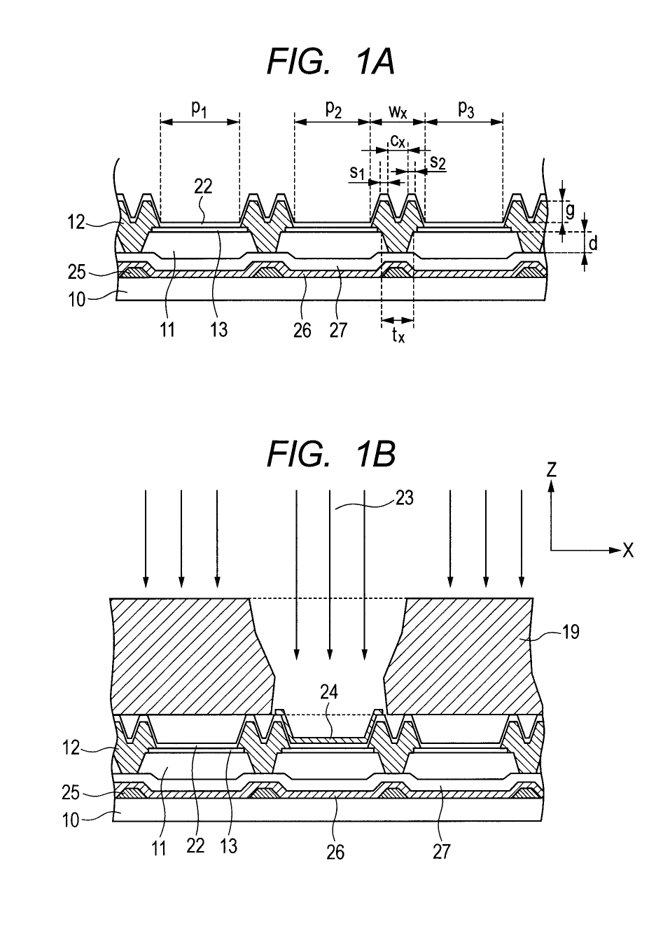

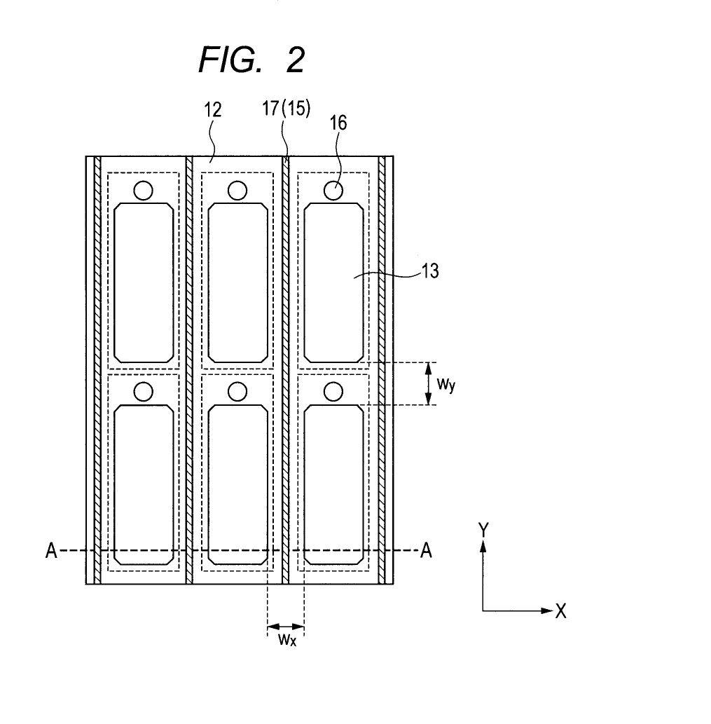

In this embodiment, a top emission organic EL display device of an active matrix drive type is exemplified, and a detailed structure of each layer is described according to a procedure of a manufacturing method therefor. FIGS. 1A and 1B are schematic diagrams illustrating a cross-sectional structure in a manufacturing process of the organic EL display device according to the embodiment of the present invention. FIG. 2 is a schematic diagram illustrating a plane structure in the manufacturing process of the organic EL display device according to this embodiment.

As illustrated in FIGS. 1A, 1B and 2, multiple first electrodes 13 are arranged in matrix on a substrate 10 of the organic EL display device according to this embodiment. Each of the first electrodes 13 is surrounded by a second insulating layer 12, and an organic compound layer including an emission layer is disposed on the first electrode 13 in a pixel aperture formed in the second insulating layer 12. Further, a second electrode (not shown) is disposed on the organic compound layers so as to be opposed to the first electrodes 13. Between the electrodes, multiple organic EL elements having the organic compound layers are disposed on the substrate 10. Note that, in the top emission organic EL display device of this embodiment, the first electrode 13 has a reflective property while the second electrode has a transparent property.

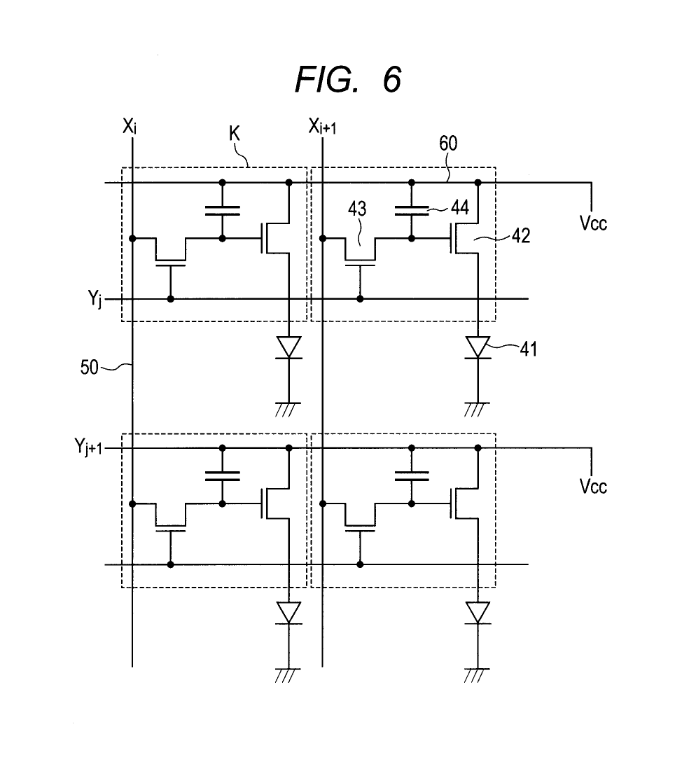

Here, FIG. 6 is a circuit diagram illustrating an example of an equivalent circuit of the organic EL display device according to this embodiment. As illustrated in FIG. 6, on the substrate 10, scanning lines 60 and signal lines 50 that are electrically separated from each other are disposed at positions orthogonal to each other. The scanning line 60 and the signal line 50 are connected via a transistor (Tr). A source electrode of a first transistor 43 is connected to a capacitor 44 and a gate electrode of a second transistor 42. A source electrode of the second transistor 42 is connected to a power supply (Vcc) and the capacitor 44. In addition, a drain electrode of the second transistor 42 is connected to the first electrode 13 of an organic EL element 41. In the organic EL display device of the active matrix drive type according to this embodiment, circuit units K enclosed by the dot lines as illustrated in FIG. 6 are formed corresponding to the individual organic EL elements and are integrated in the number of the organic EL elements. Multiple light emission pixels are formed and arranged in matrix.

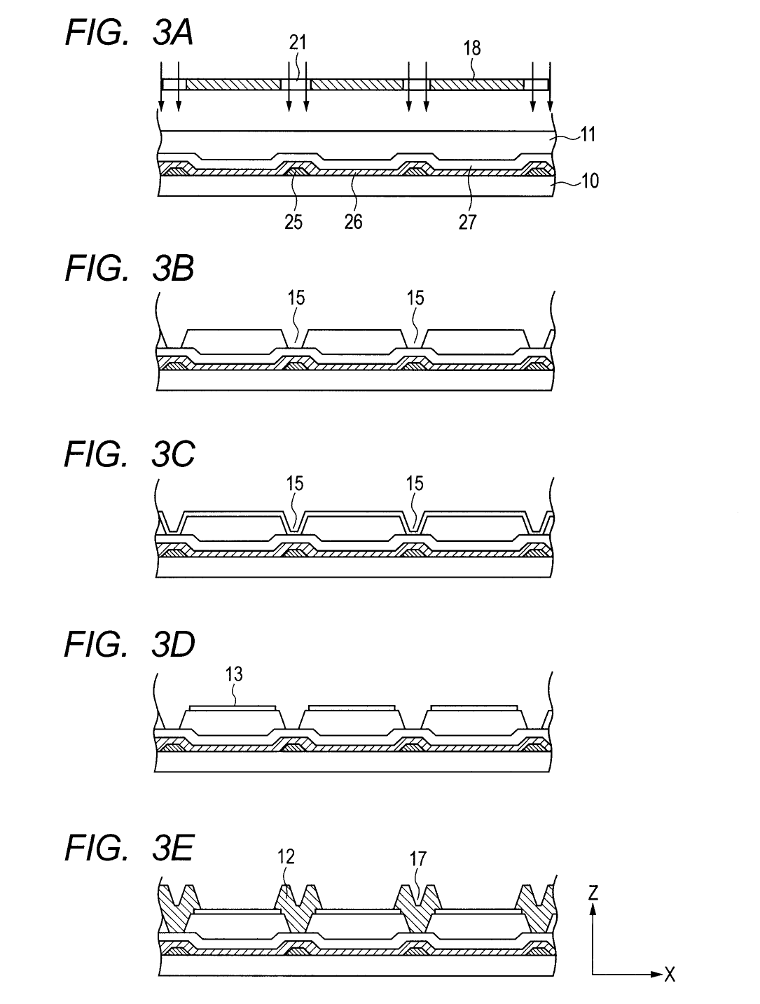

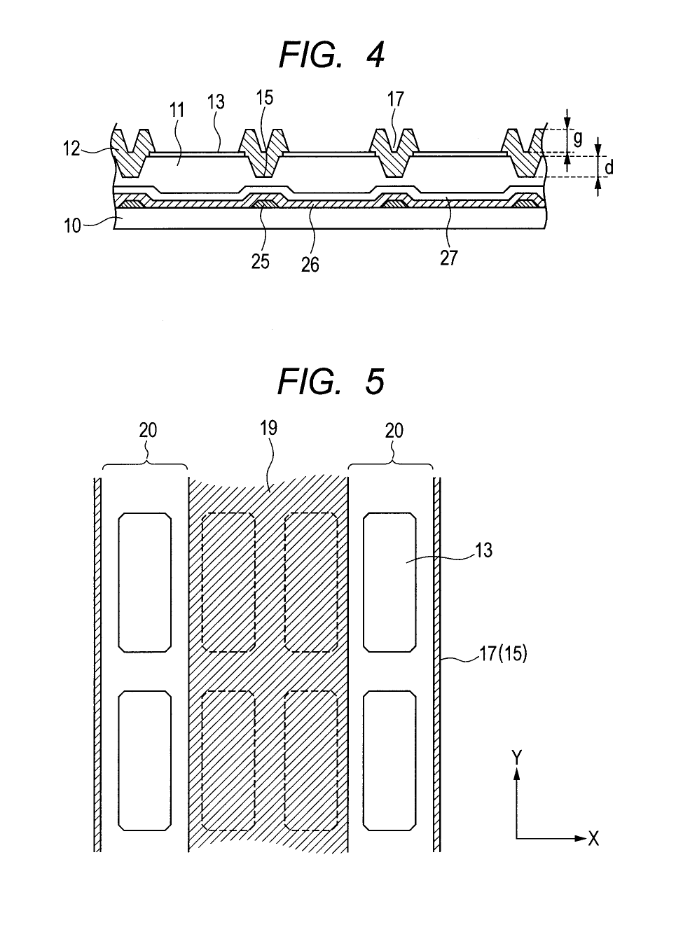

Next, with reference to FIGS. 1A to 6, a manufacturing method for the organic EL display device according to this embodiment is described according to manufacturing steps. FIGS. 3A to 3E and 4 are schematic diagrams illustrating a cross sectional structure in a manufacturing process of an organic EL display device, taken along the line A-A of FIG. 2.

First, as illustrated in FIG. 3A, gate lines 25 of the transistors, a gate insulating layer 26, and a passivation layer (insulating layer) 27 are formed on the substrate 10. The substrate surface after forming the transistors is uneven due to a wiring structure, and hence there is formed a first insulating layer (flattening layer) 11 having a flattening function for flattening the unevenness. The first insulating layer 11 is formed by applying a positive photosensitive resist by a spin coating method and irradiating the positive photosensitive resist with light such as ultraviolet rays in a predetermined region to remove, such as openings 15 to be described later.

Note that, the first insulating layer 11 is formed to have a thickness of approximately 2 μm in the case where the unevenness of the substrate surface after the transistors are formed is approximately 1 μm, for example. In addition, as the positive photosensitive resist, for example, an insulating material that has photosensitivity and contains polyimide, polybenzoxazole, or the like, but the material should not be interpreted as a limitation.

Next, exposure is performed so as to form at least contact holes 16 for connecting the first electrode 13 and the drain electrode of the transistor, which are to be connected electrically, and linear openings 15 corresponding to the regions between the first electrodes. Next, development is performed using a puddle development apparatus, and then baking is performed in a clean bake furnace to cure the resist. Thus, the contact holes 16 that can electrically connect the first electrode 13 to the drain electrode are formed in the first insulating layer 11 as illustrated in FIG. 2. Further, as illustrated in FIG. 3B, the linear openings 15 are formed in the first insulating layer 11 along the arrangement of the first electrodes 13 in regions where the transistor between the first electrodes 13 and 13 cannot electrically contact with the first electrode 13.

Next, as illustrated in FIG. 3C, the first electrodes 13 are formed on the entire surface of the first insulating layer 11 having the contact holes 16 and the openings 15. Then, the material forming the first electrode 13 is deposited not only on the first insulating layer 11 but also in the contact holes 16 and the openings 15. The first electrode 13 in this embodiment is formed to have a three-layer structure (ITO/Ag/ITO) in which a reflective metal layer made of a silver alloy is sandwiched between transparent conductive layers made of ITO, but the material to be used and a thickness thereof are not limited. For instance, the reflective metal layer may be made of an aluminum alloy or silver, and the transparent conductive layer may be made of other material such as an indium zinc oxide (IZO).

After forming the first electrode 13, as illustrated in FIG. 3D, for example, etching using a mask that is a resist pattern formed by photolithography is performed to form and pattern the first electrode 13 in which the reflective metal layer made of the silver alloy is sandwiched between the transparent conductive layers made of ITO. In other words, in this embodiment, the material forming the first electrode 13 is deposited also in the opening 15, and then the material forming the first electrode 13 in the opening 15 is removed by etching using the photolithography technology. Without limiting to this method, it is also possible to form and pattern the first electrode 13 using a vapor deposition mask, for example, so as to prevent the material forming the first electrode 13 from being deposited in the opening 15.

After that, in order to form the second insulating layer 12, the positive photosensitive resist is applied onto the substrate on which the first electrodes 13 are formed in matrix by the spin coating method, and the predetermined region to remove is irradiated with light. Here, the exposure is performed so that at least a part of the first electrode 13 is exposed to form the opening corresponding to a light emission region of the organic EL element. Next, after being developed by the puddle development apparatus, baking is performed in the clean bake furnace so that the resist is cured. Thus, as illustrated in FIG. 3E, the second insulating layer 12 having a function of partitioning the light emission regions of the organic EL elements is formed so as to surround the peripheries of the first electrodes 13. The second insulating layer 12 includes linear recesses 17 reflecting the openings 15 formed in the first insulating layer 11, between neighboring first electrodes 13. In other words, in the organic EL display device of this embodiment, the openings 15 are positively formed in the first insulating layer 11, which is to be flat. Thus, the recesses 17 reflecting the openings 15 are formed in the surface of the second insulating layer 12 formed in the regions overlapping with the openings 15.

Here, the first meaning of absence of the material forming the first electrode 13 in the opening 15 is to easily obtain sufficient depth and width of the recess 17 in the second insulating layer 12. Thus, it is possible to reduce a contact area between the second insulating layer 12 and a vapor deposition mask 19 to be described later. If the material forming the first electrode 13 exists in the opening 15, the depth and width of the recess 17 are reduced due to the material forming the first electrode 13. Particularly in a high definition display, because the interval between the first electrodes 13 and 13 is set to be small, the width of the formed opening 15 is also small. Therefore, if the material forming the first electrode 13 exists in the opening 15, a problem comes to the surface. In addition, if the material forming the first electrode 13 exists in the opening 15 and if the interval between the first electrodes 13 and 13 is set to be small, it is also worried that there is a risk of reducing yield due to a defective pattern between electrodes in the opening 15.

In addition, in the case where a reflective material is used as the material forming the first electrode 13 like this embodiment, because the material forming the first electrode 13 does not exist in the opening 15, it is possible to prevent ambient light reflection from occurring at the region.

Note that, in order to form the recess 17 in the second insulating layer 12, it is preferred that a width tx of the opening 15 in the first insulating layer 11 be equal to or larger than a depth d of the opening 15 in the first insulating layer 11, and that the depth d of the opening 15 in the first insulating layer 11 be equal to or larger than the thickness of the second insulating layer 12 as illustrated in FIG. 1A.

In addition, a recess depth g of the second insulating layer 12 formed in the region overlapping with the opening 15 formed in the first insulating layer 11 is set to a value of at least the thickness of the organic compound layer or larger. Because the recess 17 in the second insulating layer 12 is a recess reflecting the opening 15 formed in the first insulating layer 11, this recess depth g can be adjusted by a combination of the depth d and the width tx of the opening 15 in the first insulating layer 11. Therefore, in FIGS. 3A to 3E, the opening 15 passes through the first insulating layer 11, but not necessarily, and may be a recess. For instance, as illustrated in FIG. 4 which shows a cross sectional structure, taken along A-A of FIG. 2, the depth d of the opening 15 may be set to approximately a half of the first insulating layer 11. In order to form the opening 15 having a predetermined depth in the first insulating layer 11 using the positive photosensitive resist, for example, there is a method of decreasing an exposure opening space of a photomask 18 so as to reduce the irradiation amount to be relatively smaller than that in the case of forming the opening 15 in a passed-through manner, to thereby adjust the depth that can be soluble in development liquid.

It is sufficient that the recess depth g of the second insulating layer 12 is in a range of at least the thickness of the organic compound layer or larger. The reason is described below.

In the manufacturing process of the organic EL display device, vapor deposition is performed on multiple substrates successively using the same vapor deposition mask. Therefore, the vapor deposition mask and the surface of the second insulating layer 12 are brought into contact with each other repeatedly. In the organic EL elements that are formed by sequentially stacking multiple organic compound layers, when the vapor deposition mask is used for the second or subsequent layer, an organic compound adhered to the surface of the second insulating layer 12 in the previous vapor deposition step is pressed onto the vapor deposition mask. Therefore, the organic compound at the pressed part may be transferred onto the vapor deposition mask, and hence may become a foreign substance that causes a defect.

In this embodiment, the recess depth g of the second insulating layer 12 is set to be larger than the thickness of the organic compound layer. In this way, the transferring of the organic compound on the second insulating layer 12 onto the vapor deposition mask 19 can be reduced, and hence it is possible to prevent the organic compound adhered to the vapor deposition mask 19 from contacting with the second insulating layer 12. Therefore, it is preferred to set the recess depth g to be at least the thickness of the organic compound layer or larger as described above.

In addition, the contact area between the vapor deposition mask 19 and the second insulating layer 12 can be reduced more as the width of the recess 17 in the second insulating layer 12 is larger. The shape of the recess in the second insulating layer 12 can be adjusted by the width and the depth d of the opening 15 formed in the first insulating layer 11. In addition, in order to avoid a damage to the surface of the first electrode 13 or the organic compound layer formed on the surface of the first electrode 13 due to the foreign substance adhered to the vapor deposition mask 19, for example, it is preferred to set the thickness of the second insulating layer 12 to be larger than the foreign substance adhered to the vapor deposition mask 19. Specifically, it is preferred to set the thickness of the second insulating layer 12 to 0.1 μm or larger.

Note that, the manufacturing method by the photolithography technology using a photosensitive resist as the second insulating layer 12 is described above, but various organic or inorganic materials can be used as the material of the insulating layer as long as the material is an insulator having a volume resistivity of 1.0×10⁸ Ω·cm or larger. More preferably, an insulator having a volume resistivity of 1.0×10¹² Ω·cm or larger is used for the second insulating layer 12.

The description of the process after forming the second insulating layer 12 is further continued. First, a baking process is performed in a vacuum atmosphere, and a pretreatment of the substrate is performed using O₂ plasma. Next, under a state maintaining the vacuum atmosphere, multiple organic compound layers including a hole transport layer, an emission layer, an electron transport layer, and an electron injection layer are deposited sequentially by vapor deposition on the first electrode 13.

A process of forming the emission layers of different colors of red color pixels, green color pixels, and blue color pixels using the vapor deposition mask 19, in particular, is further described in detail. Here, with reference to FIG. 5, a structure of the vapor deposition mask 19 is described, which is used in a state of being in contact onto the second insulating layer 12 when the organic compound layers are deposited on the first electrode 13 by vapor deposition. FIG. 5 is an explanatory diagram illustrating a plane state in which the vapor deposition mask is brought into contact with the second insulating layer in the manufacturing method of the organic EL display device of this embodiment.

As illustrated in FIG. 5, the vapor deposition mask 19 includes vapor deposition opening portions 20 elongated in the direction in which the same color pixels are arranged, and the vapor deposition opening portions 20 are formed and arranged at a constant pitch in a mask surface. FIG. 1B illustrates a cross sectional structure in a state where the vapor deposition mask 19 illustrated in FIG. 5 is brought into contact with the second insulating layer 12 on the substrate.

With reference to FIGS. 1A and 1B, a case where the vapor deposition mask 19 is used for vapor deposition of the red color emission layer is described. As illustrated in FIG. 1A, after a hole transport layer 22 is formed, the substrate is transported to a vacuum chamber for forming the red color emission layer, and the vapor deposition mask 19 illustrated in FIG. 5 is brought into contact with the second insulating layer 12 in a positioned state. Actually, the vapor deposition mask 19 is brought into contact with the hole transport layer 22 on the second insulating layer 12. In this case, as illustrated in FIG. 1B, the vapor deposition mask 19 and the second insulating layer 12 are brought into contact with each other only at protrusions of the second insulating layer 12. In this state, a region corresponding to the first electrode 11 of the red color pixel is exposed, and a red color emission layer 24 is deposited by vapor deposition to be a predetermined thickness. A green color emission layer and a blue color emission layer are also formed in the same manner. Note that, organic compound layers except for the emission layer can be formed as continuous layers common to multiple organic EL elements in each vacuum chamber, or can be formed for each organic EL element in the same manner as the emission layer.

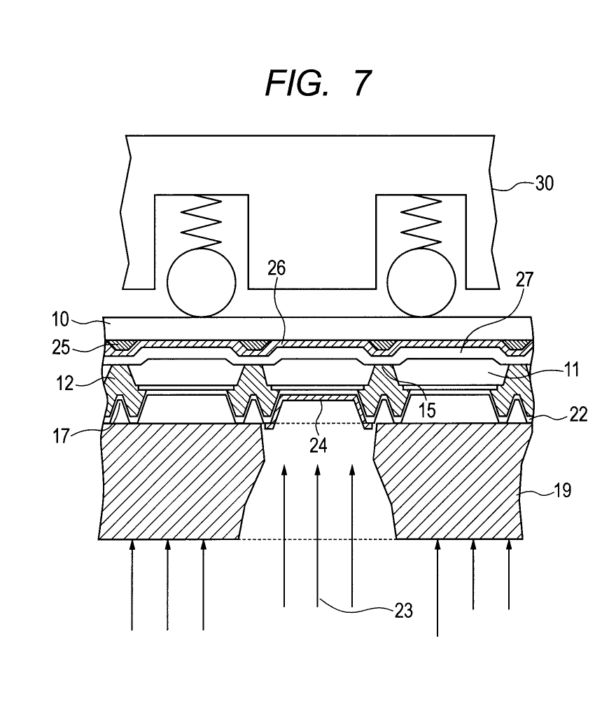

In addition, FIG. 7 is a schematic diagram illustrating a state in which a force is applied to the backside of the substrate so that the surface of the second insulating layer on the substrate is pressed to the vapor deposition mask surface in the manufacturing process of the organic EL display device according to this embodiment. During a period after the vapor deposition mask 19 is positioned with respect to the substrate until the vapor deposition of the emission layer 24 is finished, it is necessary to maintain a relative position and a contact state between the substrate and the vapor deposition mask 19 to be stable. For instance, as illustrated in FIG. 7, it is preferred to make a state in which the upper surface of the second insulating layer 12 on the substrate is pressed to the vapor deposition mask surface, by adopting a structure in which the backside of the substrate 10 is pressed by a spring using a spring load structure 30 disposed on the backside of the substrate 10.

Even in the pressed state, in the manufacturing method of the organic EL display device according to this embodiment, because the second insulating layer 12 has the recesses 17, the contact area between the second insulating layer 12 and the vapor deposition mask 19 can be reduced. Therefore, it is possible to suppress an influence that the second insulating layer 12 is damaged by the foreign substance adhered to the vapor deposition mask 19.

In addition, as another means for maintaining the contact state between the substrate and the vapor deposition mask 19 to be stable, although illustration is omitted, it is possible to use a method of disposing a magnet on the substrate backside so as to attract the vapor deposition mask 19 to the substrate by a magnetic force. In this case, it is necessary to constitute the vapor deposition mask 19 of a ferromagnetic material, and for example, Invar material, Ni, or stainless steel except austenitic stainless steel can be used.

Note that, the exemplified shape of the vapor deposition mask 19 does not limit a range to which the present invention is applied, and various known vapor deposition masks can be used.

The process after that has the same procedure as the manufacturing method of an ordinary organic EL display device. Although illustration is omitted, for example, a transparent conductive layer made of a translucent Ag alloy thin film and an indium zinc oxide is laminated on the organic compound layer, to thereby form the second electrode. Next, a protection film made of silicon nitride is formed on the transparent conductive layer. Next, a thermosetting resin is applied onto the protection film and a perimeter of the substrate. A substrate made of glass, for example, is adhered onto the resin, so as to seal by heating.

According to the manufacturing method described above, it is possible to obtain the top emission organic EL display device, which reflects the light generated in the emission layer of the organic compound layers by the surface of the first electrode 11 including the Ag alloy film, and outputs the light through the second electrode constituted of layers including the translucent Ag alloy thin film.

According to the organic EL display device and the manufacturing method therefor according to this embodiment, the opening 15 is formed between neighboring first electrodes in the first insulating layer 11, and the second insulating layer 12 is formed so as to surround the first electrode 13 in the region overlapping with the opening 15. Thus, the recess 17 is formed in the vertical direction of the substrate in the surface of the second insulating layer 12 to be brought into contact with the vapor deposition mask 19, and hence the contact area between the second insulating layer 12 and the vapor deposition mask 19 can be reduced. In other words, without increasing the number of steps and manufacturing cost, in the process of applying different color emission layers using the vapor deposition mask 19, the second insulating layer 12 hardly suffer from abrasion, scratch, or other damage, and hence it is possible to reduce a risk of a short-circuit or a leakage between electrodes due to moisture invasion.

As mentioned above, the exemplary embodiment of the present invention is described, but this is an example for describing the present invention. The present invention can be embodied in various forms different from the above-mentioned embodiment in the scope without deviating from the spirit of the present invention.

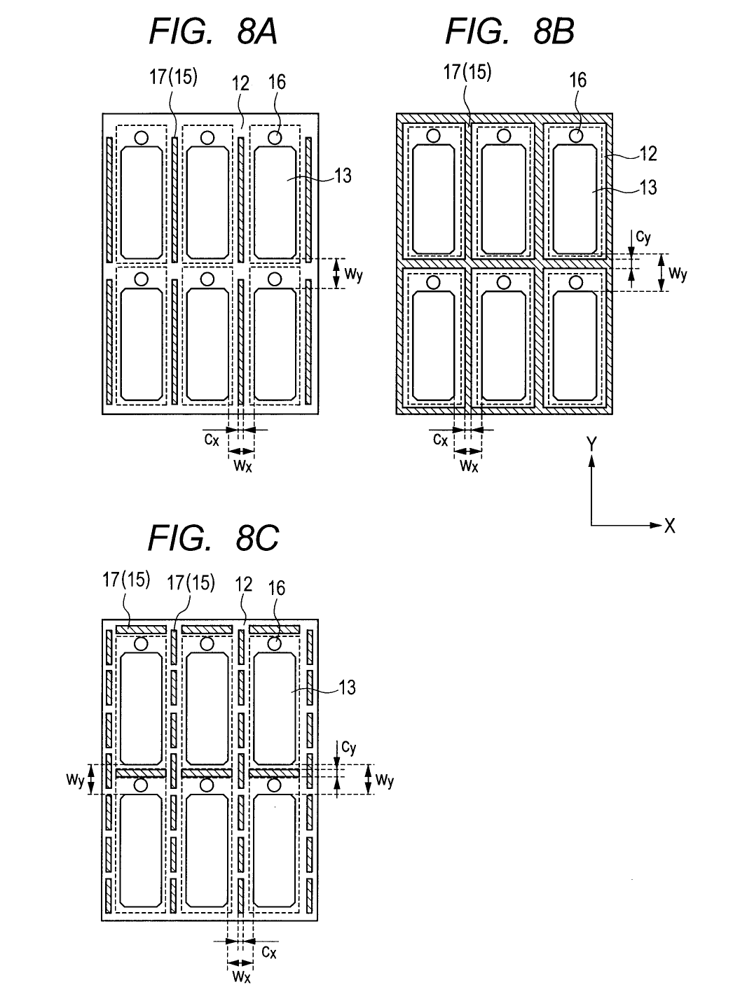

For instance, in the embodiment described above, the opening 15 and the recess 17 are formed in a linear shape as illustrated in the plane structure of FIG. 2. The present invention is not limited thereto. The shapes, the lengths, and the widths of the opening 15 and the recess 17 can be selected arbitrary as illustrated in FIGS. 8A to 8C, as long as the contact area between the vapor deposition mask 19 and the second insulating layer 12 can be reduced.

FIGS. 8A to 8C are schematic diagrams each illustrating plane structures of the recess in the second insulating layer and the opening in the first insulating layer in the organic EL display device of this embodiment. As illustrated in FIGS. 8A to 8C, for example, the opening 15 as a base of forming the recess 17 may be formed in a plane direction in a broken line shape (see FIG. 8A), or in a grating shape (see FIG. 8B), or may be disposed as a combination of multiple opening shapes (see FIG. 8C).

Note that, the opening 15 having a rectangular shape is shown here, but the shape or the layout of the opening in the present invention is not limited to the rectangular shape. For instance, a circular shape, an elliptical shape, or a triangular shape may be adopted.

Note that, if the opening 15 having the grating shape as illustrated in FIG. 8B is formed, it is possible to form the opening 15 so as to communicate to the contact hole 16 that can electrically connect the first electrode 13 to the drain electrode of the transistor.

In addition, in order to reduce ambient light reflection by the recess 17 in the second insulating layer 12, it is possible to form a layer having a light absorbing function in the region overlapping with the recess 17.

Further, an example of the display device of an active matrix type is described in the embodiment described above, but the present invention can be applied also to a display device of a simple matrix type.

Hereinafter, examples are used for describing the organic EL display device and the manufacturing method therefor of the present invention in more detail, but the present invention is not limited to those examples. Note that, as described above, for convenience sake of description, each layer is illustrated in a recognizable size and in an exaggerated manner in the drawings. Therefore, the scale of the drawings does not always correspond to the dimensions exemplified in the following examples.

### Example 1

With reference to FIGS. 1A and 1B, 2, and 3A to 3E, a manufacturing method for the organic EL display device according to Example 1 is described. FIG. 1A schematically illustrates a cross sectional structure of one pixel region, and illustrates a state where the hole transport layer 22 is formed to have the same thickness in all pixels. When multiple pixels having the cross sectional structure illustrated in FIG. 1A are arranged in matrix, a display region of the organic EL display device is constituted. In addition, three sub-pixels including p1, p2 and p3 are arranged in parallel in one pixel region. Note that, the organic EL display device described here has a pixel pitch of 191 μm and a sub-pixel size of 64 μm×191 μm.

As illustrated in FIGS. 1A and 3A, transistors are formed correspondingly to individual sub-pixels on the substrate 10. Note that, in FIGS. 1A and 1B, only gate lines 25 of the transistors, the gate insulating layer 26, and a passivation layer (insulating layer) 27 are illustrated. In order to flatten unevenness of the substrate 10, the first insulating layer 11 is first formed on the substrate. Next, as illustrated in FIG. 3B, the linear openings 15 having a width tx are formed between the first electrodes 13 and 13 of the individual sub-pixels p1, p2 and p3 in the first insulating layer 11. Here, the thickness of the first insulating layer 11 is set to 2 μm so that unevenness of the substrate can be sufficiently flattened. The depth d of the opening 15 is set to 2 μm, and the width tx of the opening 15 is set to 20 μm. Note that, the plane structure of the openings 15 formed in the first insulating layer 11 is as illustrated in FIG. 2.

The first insulating layer 11 described above is formed by applying a positive photosensitive resist containing polyimide using the spin coating method, irradiating regions to remove with exposing light, and performing a developing step and a baking step after that. Here, the regions to remove correspond to the openings 15, the contact holes 16 for electrically connecting the drain electrodes of the transistors to the first electrodes 13, and lead-out terminal portions (not shown) outside the display region.

Next, as illustrated in FIG. 3C, the material for forming the first electrode 13 is deposited on the entire surface of the first insulating layer 11. Here, a conductive oxide material containing indium tin oxide (ITO) is deposited by the sputtering method as an adhering layer to have a thickness of approximately 20 nm. On the ITO layer, a silver alloy is deposited by the sputtering method to have a thickness of approximately 100 nm. Further, on the silver alloy film, ITO is deposited by the sputtering method to have a thickness of approximately 10 nm. After that, as illustrated in FIG. 3D, a pattern of the multiple first electrodes 13 corresponding to individual pixels is formed by etching using the mask that is the resist pattern formed by usual photolithography.

After that, in order to form the second insulating layer 12, the positive photosensitive resist containing polyimide is applied by the spin coating method onto the substrate on which the first electrodes 13 are formed, and the predetermined regions to remove are irradiated with exposing light. Here, the second insulating layer 12 having pixel apertures that exposes the first electrodes 13 and covers ends of the first electrodes 13 is formed. This second insulating layer 12 is formed by the same process as the first insulating layer 11 described above, except for an exposure region.

Thus, as illustrated in FIG. 3E, the second insulating layer 12 formed to enclose the perimeters of the first electrodes 13 includes the linear recesses 17 reflecting the openings 15 formed between neighboring first electrodes 13 and 13 in the first insulating layer 11. Here, the second insulating layer 12 is formed to have a thickness of 2 μm, a width Wx of 25 μm, a recess width cx of 18 μm, and a recess depth g of approximately 1 μm. Note that, the second insulating layer 12 has a width Wy of 15 μm. Note that, S1 and S2 which are formed in the insulating layer 12 and which are regions in which height of the recesses are made high each have a width of 1 μm.

As illustrated in FIG. 1A, the hole transport layer 22 having a thickness of approximately 80 nm is formed on the entire surface of the display region on the substrate 10 described above by the vacuum deposition method. After that, the color emission layers are formed in the sub-pixels of red, green, and blue colors, respectively. As illustrated in FIG. 1B, when the vapor deposition of the emission layer is performed in the sub-pixel p2, the vapor deposition mask 19 having the opening portion for exposing the first electrode 13 of the sub-pixel p2 is brought into contact with the hole transport layer 22 deposited on the surface (protrusion) of the second insulating layer 12.

Note that, at the recess 17 in the second insulating layer 12, because the recess 17 has the depth g (1 μm) that is sufficiently larger than the thickness (80 nm) of the hole transport layer 22, the vapor deposition mask 19 is not brought into contact with the hole transport layer 22.

In this way, an evaporated substance 23 is deposited through the opening portion of the vapor deposition mask 19 so as to cover the first electrode 13 of the sub-pixel p2, and hence the emission layer 24 is formed and patterned. Note that, the contact area between the vapor deposition mask 19 and the hole transport layer 22 on the second insulating layer 12 can be reduced by approximately 30% with respect to the case where the recesses 17 are not formed.

Other emission layer patterns of the sub-pixels p1 and p2 are also formed using the vapor deposition mask 19 in the same manner. After that, the electron transport layer and the electron injection layer are formed as common layers successively in the individual vacuum chambers.

The process after that has the same procedure as the manufacturing method of the ordinary organic EL display device. Although illustration is omitted, for example, a transparent conductive layer made of a translucent Ag alloy thin film and IZO is laminated on the organic compound layer, to thereby form the second electrode. Next, a protection film made of silicon nitride is formed on the transparent conductive layer. Next, a thermosetting resin is applied onto the protection film and a perimeter of the substrate. A substrate made of glass, for example, is adhered onto the resin, so as to seal by heating.

According to the manufacturing method described above, it is possible to obtain the top emission organic EL display device, which reflects the light generated in the emission layer of the organic compound layers by the surface of the first electrode 11 including the Ag alloy film, and outputs the light through the second electrode 12 constituted of layers including the translucent Ag alloy thin film.

According to the organic EL display device and the manufacturing method therefor according to Example 1, the opening 15 having a depth of 2 μm and a width of 20 μm 12 is formed between neighboring first electrodes in the first insulating layer 11, and the second insulating layer 12 is formed so as to surround the first electrode 13 while including the region overlapping with the opening 15. Further, the surface of the second insulating layer 12 that is brought into contact with the vapor deposition mask 19 includes the recesses 17 having a depth of 1 μm in the vertical direction of the substrate and a width of 18 μm. Thus, the contact area between the vapor deposition mask 19 and the hole transport layer 22 on the second insulating layer 12 can be reduced by approximately 30% compared with the case where the recesses 17 are not formed.

The number of pixel defects due to abrasion or scratch on the second insulating layer 12 was compared between the case where the recesses were not formed in the second insulating layer 12 as a comparative example and the case where the recesses 17 were formed as Example 1. As a result, the number of pixel defects could be reduced by approximately 20% in Example 1.

### Example 2

With reference to FIG. 7, a manufacturing method for an organic EL display device according to Example 2 is described. FIG. 7 illustrates a process of forming the emission layer in the sub-pixel. Note that, the substrate described in this example has a size of 60 mm×460 mm×0.5 mmt, and 5×5 panel regions are disposed. In each panel region, the structure of the transistor, the first insulating layer 11, the first electrode 13, and the second insulating layer 12 formed on the substrate 10 is the same as in Example 1.

As illustrated in FIG. 7, when the vapor deposition of the emission layer is performed, the vapor deposition mask 19 having the opening that exposes the first electrode 13 in the sub-pixel p2 is positioned so as to contact with the hole transport layer 22 deposited on the surface of the second insulating layer 12. Particularly in this example, after positioning the substrate with respect to the vapor deposition mask 19, the substrate is pressed to the vapor deposition mask 19 by an urging force of the spring load structure 30 disposed on the backside of the substrate, and under this state, the emission layer 24 is formed. Note that, the number of points of the spring load is set to 50 in the substrate surface, and a load at each point is set to 10 g.

According to the organic EL display device manufactured by the same method as in Example 1 except for the above description, the contact area between the vapor deposition mask 19 and the hole transport layer 22 on the second insulating layer 12 can be reduced similarly to Example 1. In addition, it is possible to maintain the relative position and the contact state between the substrate and the vapor deposition mask 19 to be stable during the period after the vapor deposition mask 19 is positioned with respect to the substrate until the vapor deposition of the emission layer is finished.

The number of pixel defects due to abrasion or scratch on the second insulating layer 12 when the above-mentioned load was applied to the substrate backside was compared between the case where the recesses were not formed in the second insulating layer 12 as a comparative example and the case where the recesses 17 were formed as Example 2. As a result, the number of pixel defects could be reduced by approximately 20% in this example. In addition, good mask vapor deposition accuracy of ±10 μm or smaller could be achieved in all of 5×5 panel regions in the substrate.

### Example 3

With reference to FIG. 8B, a manufacturing method for an organic EL display device according to Example 3 is described. FIG. 8B schematically illustrates a plane structure of a 3×2 sub-pixel region, and multiple sub-pixel regions are disposed in matrix so that the display region of the organic EL display device is constituted.

The second insulating layer 12 illustrated in FIG. 8B is formed so as to have the recesses 17 reflecting the openings 15 by forming the grating-like openings 15 in the peripheries of the first electrodes 13 in the first insulating layer 11. The grating-like opening 15 is formed to communicate to the contact hole 16 that can electrically connect the first electrode 13 to the drain electrode of the transistor.

The opening 15 having a depth of 2 μm and a width of 20 μm is formed in the first insulating layer 11 between the first electrodes neighboring in an X direction in FIG. 8B, and the second insulating layer 12 is formed to surround the first electrode 13 while including the region overlapping with the opening 15. Thus, the surface of the second insulating layer 12 contacting with the vapor deposition mask 19 has the recesses 17 having a depth of 1 μm in the vertical direction of the substrate and a width Cx of 18 μm. In addition, the opening 15 having a depth of 2 μm and a width of 10 μm is formed in the first insulating layer 11 between the first electrodes neighboring in a Y direction in FIG. 8B, and the second insulating layer 12 is formed to surround the first electrode 13 while including the region overlapping with the opening 15. Thus, the surface of the second insulating layer 12 contacting with the vapor deposition mask 19 has the recesses 17 having a depth of 1 μm in the vertical direction of the substrate and a width Cy of 12 μm. Note that, the second insulating layer 12 has a thickness of 2 μm.

According to the organic EL display device manufactured by the same method as in Example 1 except for the above description, the contact area between the vapor deposition mask 19 and the hole transport layer 22 on the second insulating layer 12 can be reduced by approximately 60% compared with the case where the recesses are not formed.

The number of pixel defects due to abrasion or scratch on the second insulating layer 12 was compared between the case where the recesses were not formed in the second insulating layer 12 as a comparative example and the case where the recesses 17 were formed as Example 3. As a result, the number of pixel defects could be reduced by approximately 50% in this example.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2010-183874, filed Aug. 19, 2010, which is hereby incorporated by reference herein in its entirety.

What is claimed is:

1. An organic electroluminescence display device, comprising:
a first insulating layer formed on a substrate;
multiple first electrodes disposed on the first insulating layer;
one of a first opening and a first recess formed in the first insulating layer at a periphery of each of the multiple first electrodes;
a second insulating layer that covers the one of the first opening and the first recess, and has second openings corresponding to the multiple first electrodes;
an organic compound layer disposed on the each of the multiple first electrodes; and
a second electrode formed on the organic compound layer, wherein:
a material forming the each of the multiple first electrodes is absent in the one of the first opening and the first recess; and
the second insulating layer has a second recess formed in a surface thereof, corresponding to the one of the first opening and the first recess of the first insulating layer.

2. The organic electroluminescence display device according to claim 1, further comprising a transistor disposed on the substrate, wherein:
the first insulating layer is disposed on the transistor; and
the first insulating layer has the first opening in a region in which the transistor does not electrically contact with the first electrode, and has a contact hole for electrically connecting the transistor to the first electrode.

3. The organic electroluminescence display device according to claim 2, wherein the first opening of the first insulating layer communicates to the contact hole.

4. The organic electroluminescence display device according to claim 1, wherein the second recess of the second insulating layer has a depth equal to or larger than a thickness of the organic compound layer.

5. The organic electroluminescence display device according to claim 1, wherein the first opening of the first insulating layer has a width equal to or larger than a depth of the first opening, and the depth of the first opening of the first insulating layer is equal to or larger than a thickness of the second insulating layer.

6. The organic electroluminescence display device according to claim 1, wherein in a plane directin, the first opening of the first insulating layer is formed any one of in a linear shape, in a broken line shape, in a grating shape, and in a combination thereof.

7. A method of manufacturing an organic electroluminescence display device, comprising:
forming a first insulating layer on a substrate;
forming one of a first opening and a first recess in the first insulating layer;
forming multiple first electrodes on the first insulating layer;
forming a second insulating layer having second openings corresponding to the multiple first electrodes in regions overlapping with the one of the first opening and the first recess;
forming an organic compound layer for covering the multiple first electrodes by bringing a vapor deposition mask into contact with a surface of the second insulating layer; and
forming a second electrode on the organic compound layer, wherein:
the forming multiple first electrodes is performed so that a material forming each of the multiple first electrodes is absent in the one of the first opening and the first recess of the first insulating layer; and
the forming a second insulating layer includes forming the second insulating layer corresponding to the first opening of the first insulating layer, and forming a second recess in the surface of the second insulating layer.

8. The method of manufacturing an organic electroluminescence display device according to claim 7, further comprising forming a transistor on the substrate,
wherein the forming a first insulating layer includes:
forming the first opening in a region in which the transistor does not electrically contact with the first electrode, and forming a contact hole for electrically connecting the transistor to the first electrode, the first opening and the contact hole being formed simultaneously; and
forming the first opening and the contact hole so as to communicate to each other in the first insulating layer.

9. The method of manufacturing an organic electroluminescence display device according to claim 7, wherein the forming an organic compound layer includes, when the vapor deposition mask is brought into contact with the surface of the second insulating layer to form an organic compound layer on the first electrode via a vapor deposition opening portion of the vapor deposition mask, applying an urging force to a backside of the substrate so that the surface of the second insulating layer is pressed to the vapor deposition mask.

10. The method of manufacturing an organic electroluminescence display device according to claim 7, wherein the forming an organic compound layer includes, when the vapor deposition mask is brought into contact with the surface of the second insulating layer to form an organic compound layer on the first electrode via a vapor deposition opening portion of the vapor deposition mask, attracting the vapor deposition mask to the substrate by a magnetic force so that a surface of the vapor deposition mask is pressed to the surface of the second insulating layer.
